(19) United States
(12) Patent Application Publication
(10) Pub. No.: US 2009/0286397 A1
(43) Pub. Date: Nov. 19, 2009

(54) SELECTIVE INDUCTIVE DOUBLE PATTERNING

(75) Inventor: S. M. Reza Sadjadi, Saratoga, CA (US)

Correspondence Address: Beyer Law Group LLP, P.O. BOX 1687, Cupertino, CA, 95015-1687, US

(73) Assignee: LAM RESEARCH CORPORATION, Fremont, CA (US)

(21) Appl. No.: 12/121,711

(22) Filed: May 15, 2008

(51) Int. Cl. H01L 21/44; C23C 16/00

(52) U.S. Cl. 438/680; 118/723 R; 257/E21.476

(57) ABSTRACT

An inductively coupled power (ICP) plasma processing chamber for forming semiconductor features is provided. A plasma processing chamber is provided, comprising a vacuum chamber, at least one antenna adjacent to the vacuum chamber for providing inductively coupled power in the vacuum chamber, a substrate support for supporting a silicon substrate within the plasma processing chamber, a pressure regulator, a gas inlet for providing gas into the plasma processing chamber, and a gas outlet for exhausting gas from the plasma processing chamber. A gas distribution system is in fluid connection with the gas inlet for providing a first gas and a second gas, wherein the gas distribution system can substantially replace one of the first gas and the second gas in the plasma zone with the other of the first gas and the second gas within a period of less than 5 seconds.

### BACKGROUND OF THE INVENTION

The present invention relates to the formation of semiconductor devices.

During semiconductor wafer processing, features of the semiconductor device are defined in the wafer using well-known patterning and etching processes. In these processes, a photoresist (PR) material is deposited on the wafer and then is exposed to light filtered by a reticle. The reticle is generally a glass plate that is patterned with exemplary feature geometries that block light from propagating through the reticle.

After passing through the reticle, the light contacts the surface of the photoresist material. The light changes the chemical composition of the photoresist material such that a developer can remove a portion of the photoresist material. In the case of positive photoresist materials, the exposed regions are removed, and in the case of negative photoresist materials, the unexposed regions are removed. Thereafter, the wafer is etched to remove the underlying material from the areas that are no longer protected by the photoresist material, and thereby define the desired features in the wafer.

### SUMMARY OF THE INVENTION

To achieve the foregoing and in accordance with the purpose of the present invention, an inductively coupled power (ICP) plasma processing chamber for forming semiconductor features is provided. A plasma processing chamber is provided, comprising a vacuum chamber, at least one antenna adjacent to the vacuum chamber for providing inductively coupled power in the vacuum chamber, a substrate support for supporting a silicon substrate within the plasma processing chamber, a pressure regulator for regulating the pressure in the plasma processing chamber, a gas inlet for providing gas into the plasma processing chamber, and a gas outlet for exhausting gas from the plasma processing chamber. A gas distribution system is in fluid connection with the gas inlet for providing a first gas and a second gas, wherein the gas distribution system can substantially replace one of the first gas and the second gas in the plasma zone with the other of the first gas and the second gas within a period of less than 5 seconds.

In another manifestation of the invention, a method for forming semiconductor features is provided. A wafer is loaded into an inductively coupled plasma (ICP) processing chamber, wherein at least one conductive layer and at least one dielectric layer are formed over the wafer and a mask of an organic material is formed over the at least one conductive layer and at least one dielectric layer. An inorganic material layer is deposited on the organic material mask, comprising flowing an inorganic material deposition gas into the process chamber, providing an inductively coupled energy to form the inorganic material deposition gas into a plasma, which deposits a layer of inorganic material on the organic material mask, and stopping the flow of the inorganic material deposition gas.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart of a process that may be used in an embodiment of the invention.

FIG. 2 is a schematic view of a plasma processing chamber that may be used in practicing the invention.

FIG.'S 3A-B illustrates a computer system, which is suitable for implementing a controller used in embodiments of the present invention.

FIG.'S 4A-H are schematic cross-sectional views of a stack processed according to an embodiment of the invention.

FIG. 5 is a more detailed flow chart for forming inorganic spacers.

FIG. 6 is a more detailed flow chart of a process step.

FIG. 7 shows a preferred embodiment of a gas distribution system.

FIG.'S 8A-B are simplified views of a processing system, which provides a more detailed view of an embodiment of a driver for a confinement mechanism.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

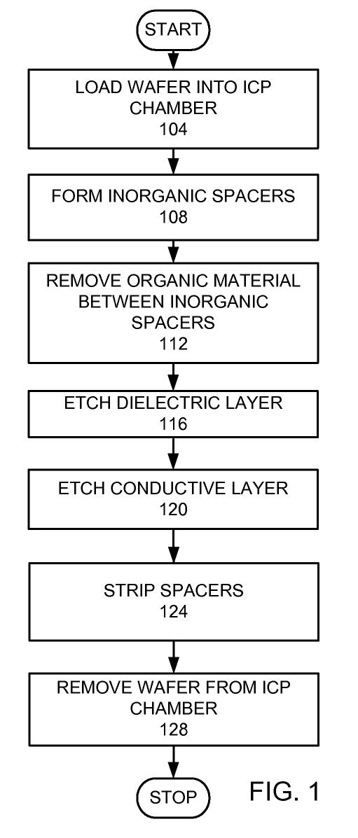

To facilitate understanding, FIG. 1 is a high level flow chart of a process that may be used in an embodiment of the invention. A wafer is loaded into an inductively coupled plasma (ICP) processing chamber (step 104). Inorganic spacers are formed around an organic material mask (step 108). The inorganic spacers may be of an inorganic material such as silicon (Si) containing films, such as SiO₂, SiON, SiC, SiOC, SiNC, or Si₃N₄. The organic material layer may be a photoresist material. Organic material is removed from between the inorganic spacers (step 112). A dielectric layer above the wafer and below the openings between the inorganic spacers is etched (step 116). A conductive layer above the wafer and below the openings between the inorganic spacers is etched (step 120). The inorganic spacers are stripped (step 124). In another embodiment, the inorganic spacers are automatically removed when etching the inorganic or conductive layers, so that a separate stripping is not needed. The wafer is removed from the ICP chamber (step 128). In various embodiments, the order of the etching the dielectric layer, the etching the conductive layer, and the stripping the inorganic spacers may be in various orders.

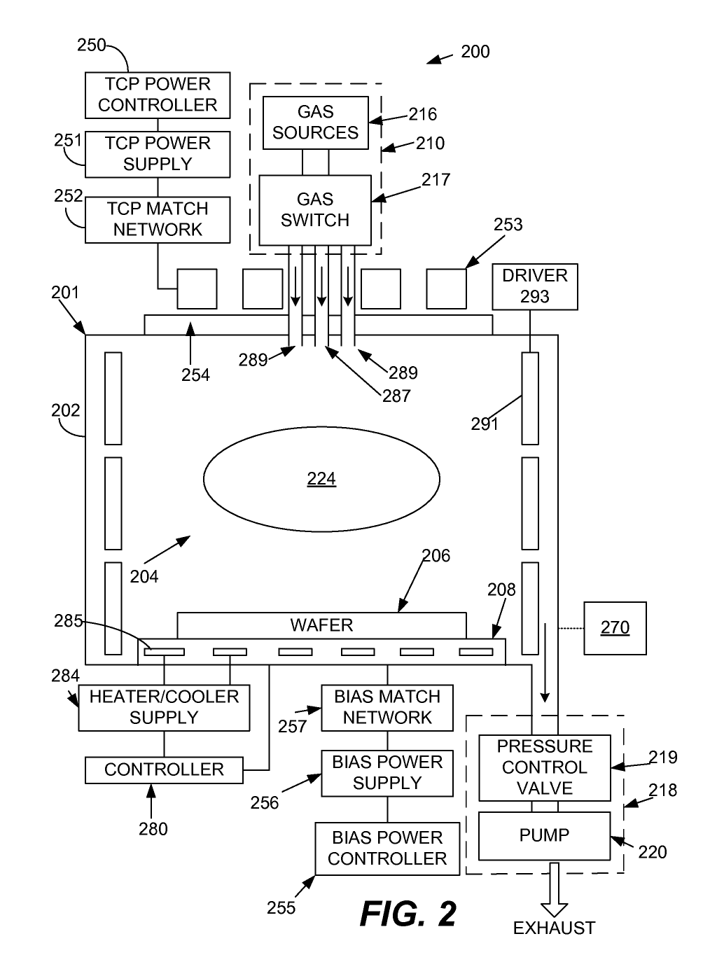

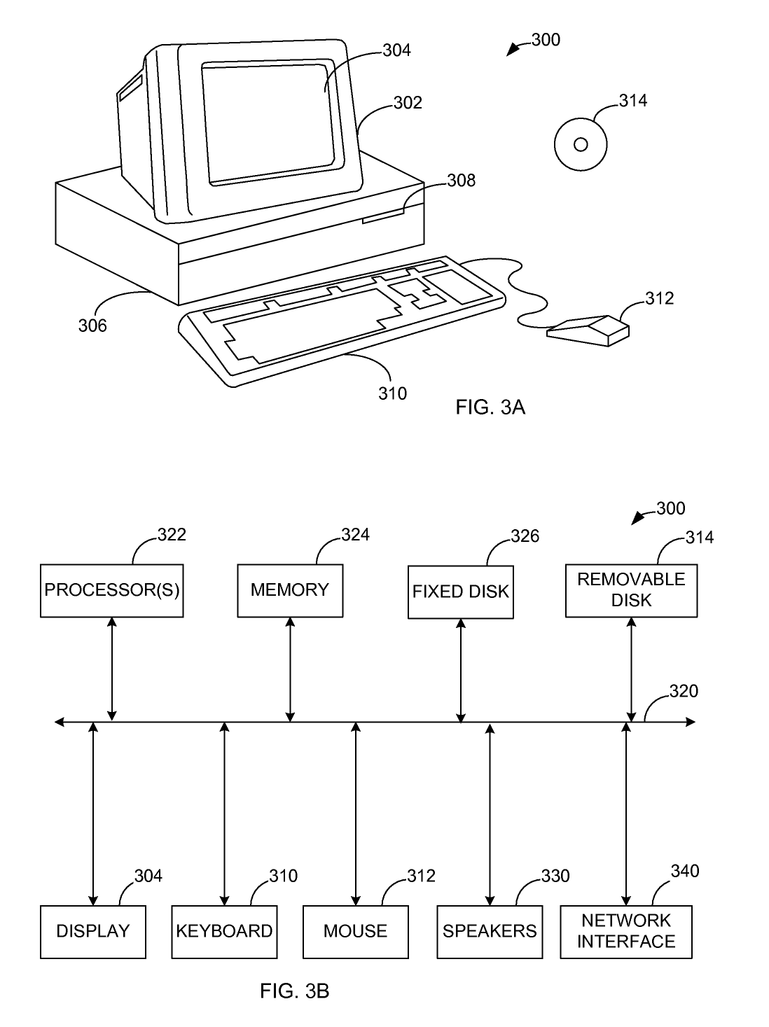

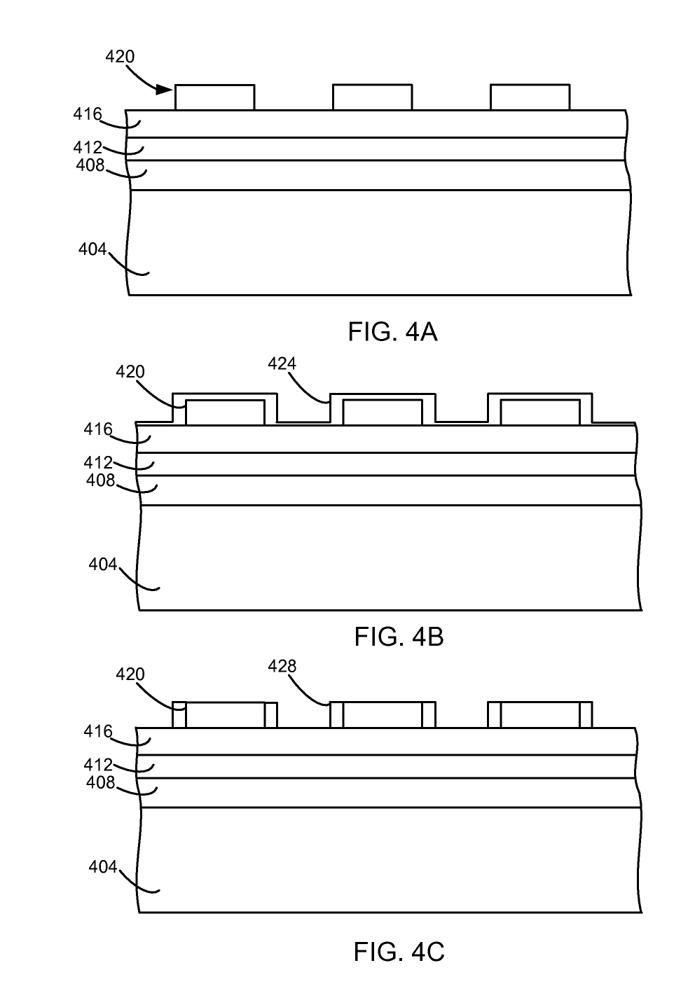

FIG. 2 illustrates a processing tool that may be used in an implementation of the invention. FIG. 2 is a schematic view of a plasma processing system 200, including a plasma processing tool 201. The plasma processing tool 201 is an inductively coupled plasma (ICP) etching tool and includes a plasma reactor 202 having a plasma processing chamber 204 therein. A TCP power controller 250 and a bias power controller 255, respectively, control a TCP power supply 251 and a bias power supply 256 influencing the plasma 224 created within plasma chamber 204.

The TCP power controller 250 controls the TCP power supply 251 configured to supply a radio frequency signal at 13.56 MHz, tuned by a TCP match network 252, to a TCP coil 253 located near the plasma chamber 204. An RF transparent window 254 is provided to separate TCP coil 253 from plasma chamber 204 while allowing energy to pass from TCP coil 253 to plasma chamber 204.

The bias power controller 255 sets a set point for bias power supply 256 configured to supply an RF signal, tuned by bias match network 257, to a chuck electrode 208 located within the plasma chamber 204 creating a direct current (DC) bias above electrode 208 which is adapted to receive a substrate 206, such as a semi-conductor wafer work piece, being processed.

A gas supply mechanism or gas source 210 includes a source or sources of gas or gases 216 attached via a gas switch 217, which is able to quickly switch between different gases, to supply the proper chemistry in a proper switching cycle required for the process to the interior of the plasma chamber 204. In this embodiment, the gas inlet has an inner inlet 287, closer to the center of the chamber, and outer inlets 289, further from the center of the chamber. The gas switch is able to provide different gas mixtures to the center and outer zones of the chambers, by providing a different gas mixture to the inner inlet 287 than the gas mixture provided to the outer inlet 289. A gas exhaust mechanism 218 includes a pressure control valve 219 and exhaust pump 220 and removes particles from within the plasma chamber 204 and maintains a particular pressure within plasma chamber 204.

A temperature controller 280 controls the temperature of a temperature control system provided within the chuck electrode 208 by controlling a heater/cooler supply 284. The heater/cooler supply 284 is directly connected to a plurality of temperature control elements 285, so that the heater/cooler supply 284 may individually control multiple zones to allow a temperature control of <1° C. The heater/cooler supply is able to provide heating and cooling from −10° C. to 120° C. The plasma processing system also includes electronic control circuitry 270. The plasma processing system may also have an end point detector.

A movable confinement mechanism 291 is spaced from the substrate support within and the chamber walls within the chamber, where the confinement mechanism defines the plasma zone 224 within the confinement mechanism and extending from the substrate support to the confinement mechanism wall. A drive system 293 is able to move the confinement mechanism to adjust the pressure in the plasma zone. Such adjustment may be made during wafer processing.

FIG.'S 3A and 3B illustrate a computer system 300, which is suitable for implementing a controller for control circuitry 270 used in embodiments of the present invention. FIG. 3A shows one possible physical form of the computer system. Of course, the computer system may have many physical forms ranging from an integrated circuit, a printed circuit board, and a small handheld device up to a huge super computer. Computer system 300 includes a monitor 302, a display 304, a housing 306, a disk drive 308, a keyboard 310, and a mouse 312. Disk 314 is a computer-readable medium used to transfer data to and from computer system 300.

FIG. 3B is an example of a block diagram for computer system 300. Attached to system bus 320 is a wide variety of subsystems. Processor(s) 322 (also referred to as central processing units, or CPUs) are coupled to storage devices, including memory 324. Memory 324 includes random access memory (RAM) and read-only memory (ROM). As is well known in the art, ROM acts to transfer data and instructions uni-directionally to the CPU and RAM is used typically to transfer data and instructions in a bi-directional manner. Both of these types of memories may include any suitable of the computer-readable media described below. A fixed disk 326 is also coupled bi-directionally to CPU 322; it provides additional data storage capacity and may also include any of the computer-readable media described below. Fixed disk 326 may be used to store programs, data, and the like and is typically a secondary storage medium (such as a hard disk) that is slower than primary storage. It will be appreciated that the information retained within fixed disk 326 may, in appropriate cases, be incorporated in standard fashion as virtual memory in memory 324. Removable disk 314 may take the form of any of the computer-readable media described below.

CPU 322 is also coupled to a variety of input/output devices, such as display 304, keyboard 310, mouse 312, and speakers 330. In general, an input/output device may be any of: video displays, track balls, mice, keyboards, microphones, touch-sensitive displays, transducer card readers, magnetic or paper tape readers, tablets, styluses, voice or handwriting recognizers, biometrics readers, or other computers. CPU 322 optionally may be coupled to another computer or telecommunications network using network interface 340. With such a network interface, it is contemplated that the CPU might receive information from the network, or might output information to the network in the course of performing the above-described method steps. Furthermore, method embodiments of the present invention may execute solely upon CPU 322 or may execute over a network such as the Internet in conjunction with a remote CPU that shares a portion of the processing.

In addition, embodiments of the present invention further relate to computer storage products with a computer-readable medium that have computer code thereon for performing various computer-implemented operations. The media and computer code may be those specially designed and constructed for the purposes of the present invention, or they may be of the kind well known and available to those having skill in the computer software arts. Examples of tangible computer-readable media include, but are not limited to: magnetic media such as hard disks, floppy disks, and magnetic tape; optical media such as CD-ROMs and holographic devices; magneto-optical media such as floptical disks; and hardware devices that are specially configured to store and execute program code, such as application-specific integrated circuits (ASICs), programmable logic devices (PLDs) and ROM and RAM devices. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

### EXAMPLES

FIG. 4A is a schematic cross-sectional view of a wafer 404. In this example, the wafer 404 is a silicon wafer, which forms a substrate. A plurality of various layers is formed over the wafer 404. In this example, a conductive layer 408 is formed over the silicon wafer 404, an intermediate layer 412, which can be any kind of film, such as a dielectric, organic or conductive layer, is formed over the conductive layer 408, and an inorganic dielectric layer 416 is formed over the intermediate layer 412. An organic material mask 420 formed from photoresist is placed over the dielectric layer 416. The organic material mask 420 is preferably a photoresist mask. In other embodiments, various combinations of dielectric and conductive layers may be disposed between the organic material mask and the wafer. The wafer 404 is placed in the plasma processing system 200 (step 104).

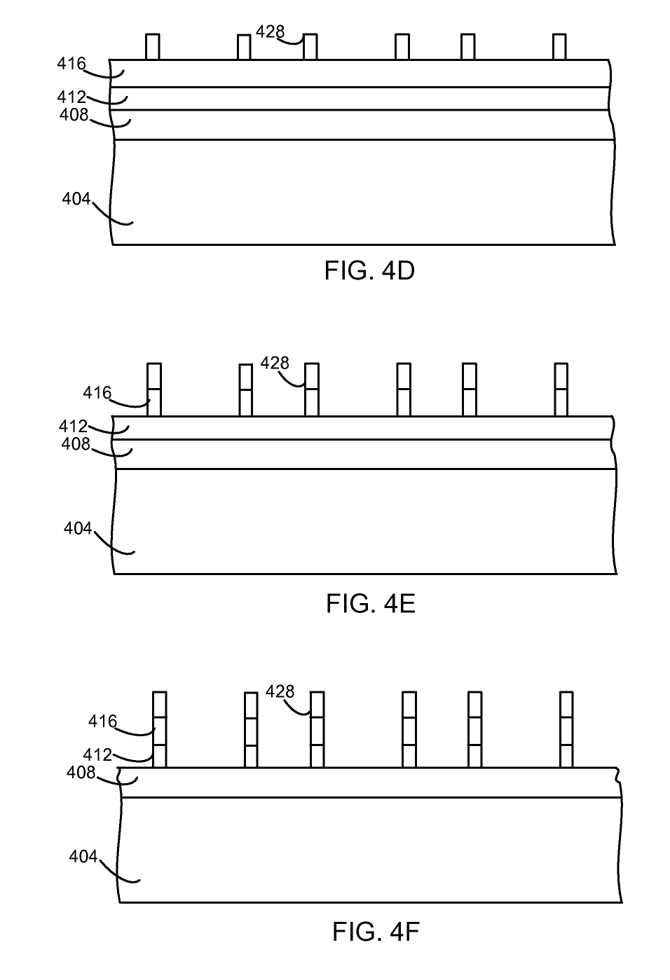

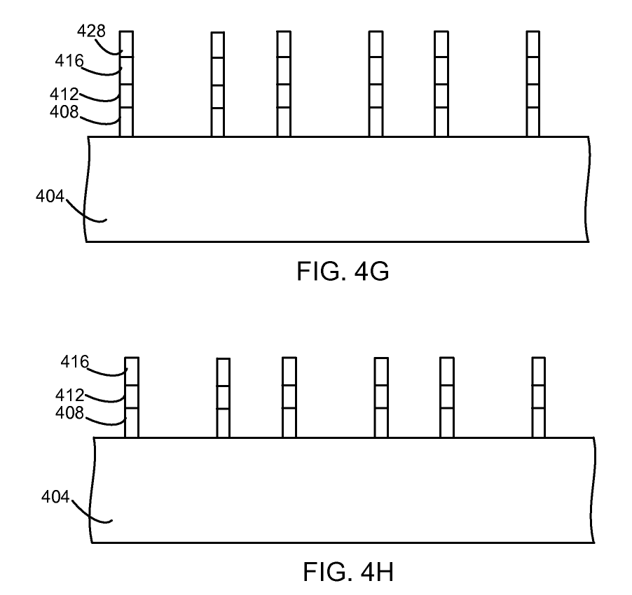

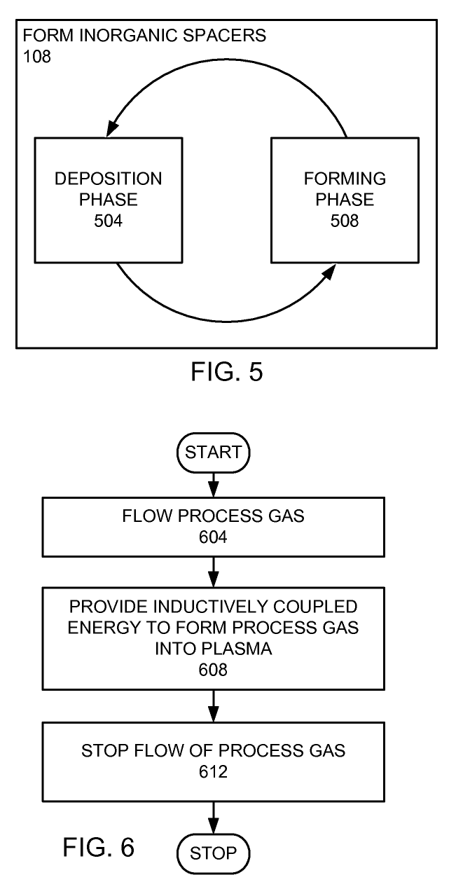

Inorganic spacers are formed on sides of the organic material mask (step 108). FIG. 5 is a more detailed flow chart of the forming the inorganic spacers (step 108). In this embodiment, such a process comprises performing a plurality of cycles, wherein each cycle comprises deposition phase (step 504) for depositing a layer of inorganic material on the organic photoresist mask and a forming phase (step 508) for forming the deposited organic layer into spacers. FIG. 4B is a schematic view of the stack after a deposition layer 424 has been formed on the organic material mask 420 after a deposition phase. The forming phase may etch back the inorganic layer deposited on horizontal surfaces and forming the sidewalls. In another embodiment, the forming phase may chemically react the deposited inorganic layer to form different inorganic material spacers on sidewalls of the organic material mask. For example, if the deposited layer is silicon, oxygen may be used to form the silicon layer into silicon oxide to provide silicon oxide spacers. FIG. 6 is a more detailed flow chart of a process that may be used in some of the processes steps or phases. For example, the deposition phase 504 would comprise flowing a process gas into the process chamber (step 604), providing inductively coupled energy to form the process gas into a plasma (step 608), and stopping the flow of the process gas (step 612). In this example, the process gas would be a deposition gas to deposit an inorganic material. Similarly, the forming phase would also provide a process gas, use inductively coupled energy to form the process gas into a plasma, and then stop the flow of the process gas. During this phase the process gas may be an etch gas. The deposition gas is different than the forming gas, which is why flow of the deposition gas is stopped before the forming phase. FIG. 4C is a view after the formation of the inorganic spacers 428 is completed.

An example recipe for using a single step to form the inorganic material spacers provides a pressure of 10 mtorr. The RF power at 13.56 MHz is provided at a power of 200 Watts. No bias voltageis provided. A process gas of 0.5 sccm SiH₄, 100 sccm Ar, and 10 sccm O₂ is provided.

In another example, a plurality of cycles is provided with a depositon phase and a forming phase, which in this example is an oxidation phase. For the deposition phase a pressure of: 10 mtorr is provided. The RF power at 13.56 MHz is provided at a power of 200 Watts. No bias voltage is provided. A process gas of 0.5 sccm SiH₄, 100 sccm Ar, and 10 sccm O₂ is provided for 1 second to a few seconds and then stopped. For the forming phase, which is an oxidation step a pressure of 50 mtorr is provided. The RF power at 13.56 MHz is provided at a power of 200 Watts. No bias voltage is provided. A process gas of 40 sccm O₂ is provided for 4 seconds, and then stopped. The deposition and forming phases are preferably repeated more than 4 times, where the number of cycles depends on the desired shape.

In this example, it is desirable to switch between the deposition phase and the forming phase in less than 5 seconds, where the switching replaces in the entire plasma zone the deposition phase gas with the forming phase gas in less than 5 seconds. More preferably, one gas may be replaced with another gas in the entire plasma zone in less than 1 second. Preferably, each phase, the deposition phase and the forming phase, of a cycle has a period of less than 10 seconds. Preferably, each cycle has a period that is less than 20 seconds. More preferably, each cycle has a period that is less than 5 seconds. It may also be desirable to provide different gases to different zones in the chamber. For example, providing different gas ratios at the center zone of the chamber compared to peripheral zones of the chamber. Such gas switching systems that supply different gas ratios to different zones are described for a capacitively couple plasma system in US Patent Application Publication 2007/0066038 A1, entitled “Fast Gas Switching Plasma Processing Apparatus,” by Sadjadi et al., and which is incorporated by reference for all purposes. This fast switching allows the period of each cycle to be as small as 0.5 seconds.

In this example, the organic material between the inorganic spacers is etched away, possibly by using a stripping process to remove the organic material (step 112). This may be accomplished by providing a process gas (step 604), providing an inductively coupled energy to form the process gas into a plasma (step 608), and then stopping the process gas (step 612). An example of a process gas for removing the organic material would be oxygen. FIG. 4D is a schematic view, after the organic material has been stripped.

In an example recipe for this stripping process a pressure of 50 mtorr is provided. The RF power at 13.56 MHz is provided at a power of 200 Watts. No bias voltageis provided. A process gas of 100 sccm O₂ is provided.

Since in this example the dielectric layer 416 is on top, the dielectric layer 416 is etched first (step 116). In this example, a single process is used for the dielectric etch. In other embodiments a cyclical process with at least two phases may be used for the dielectric etch. In this example, a process gas is flowed into the process chamber (step 604). An inductively coupled energy is used to form the process gas into a plasma (step 608). The flow of the process gas is stopped (step 612). FIG. 4E is a schematic view after the dielectric layer is etched.

In this embodiment the dielectric layer 416 may comprises at least one of any silicon containing films such as SiO₂, Si₃N₄, SiC, SiON, SiOC, or organic films such as Amorphous Carbon, PR or derivatives of these films.

In an embodiment, where the dielectric layer is SiO₂, an example recipe for the etching the dielectric layer would provide a chamber pressure of 10 mtorr. The RF power at 13.56 MHz is provided at a power of 200 Watts. A 200 volt bias voltage is provided. A process gas of 110 sccm CHF₃ and 30 sccm He is provided.

In this embodiment, the intermediate layer 412 is then etched (step 120). FIG. 4F is a view after the intermediate layer has been etched.

In this embodiment the intermediate layer may be an inorganic dielectric material such as a silicon oxide, Silicon nitride, or silicon oxynitride based material, or an organic layer, or a conductive layer.

In another embodiment, the intermediate layer etch may use a plurality of cycles, where each cycle has at least two phases.

In this embodiment, a conductive layer etch is performed on the conductive layer 408 (step 116). Such an etch may be performed in multiple steps in a cycle or in a single step. FIG. 4G is a view after the conductive layer etch.

An example of conductive layers would be polysilicon, W, and tungsten silicide. For a polysilicon conductive layer, an example of a conductive layer etch would provide a pressure of 2 mtorr. The RF power at 13.56 MHz is provided at a power of 1000 Watts. A 200 volt bias voltage is provided. A process gas of 20 sccm HBr and 20 sccm O₂ is provided.

If some of the inorganic spacers remain after the etching is completed, the inorganic spacers may be etched away (step 124). In such a process, a process gas is provided into the ICP chamber. An ICP power is supplied to form the process gas into a plasma, which removes the inorganic spacers. The process gas is then stopped. FIG. 4H is a view after the inorganic spacers have been removed.

A sample recipe for removing the inorganic spacers provides a pressure of 100 mtorr. The RF power at 13.56 MHz is provided at a power of 100 Watts. No bias voltageis provided. A process gas of 5 sccm CF₄ is provided.

In another embodiment, the removal of the inorganic spacers may use a plurality of cycles where each cycle has at least two phases.

The wafer 404 is then removed from the ICP chamber (step 128). Therefore, in this embodiment the formation of the inorganic spacers on the sidewalls of the organic material mask, the dielectric layer etching, the conductive layer etching, the removal of the organic material mask, and the removal of the inorganic sidewall spacers were all done in situ in the ICP chamber.

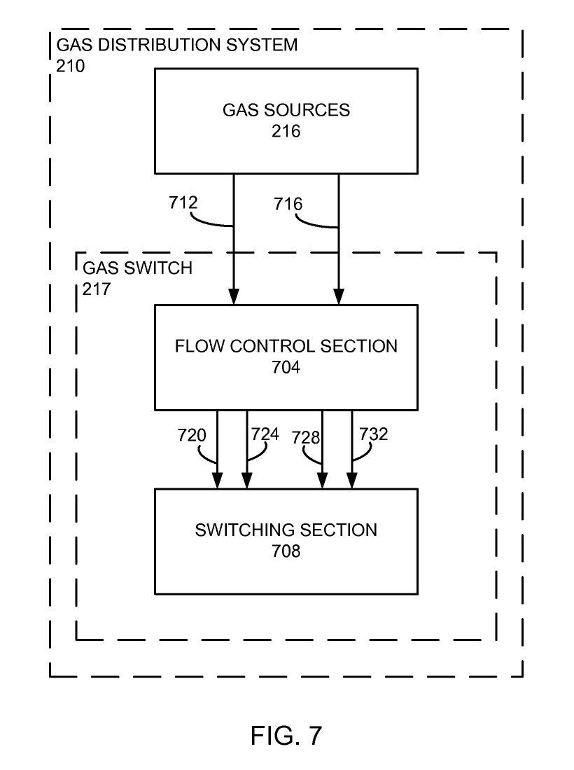

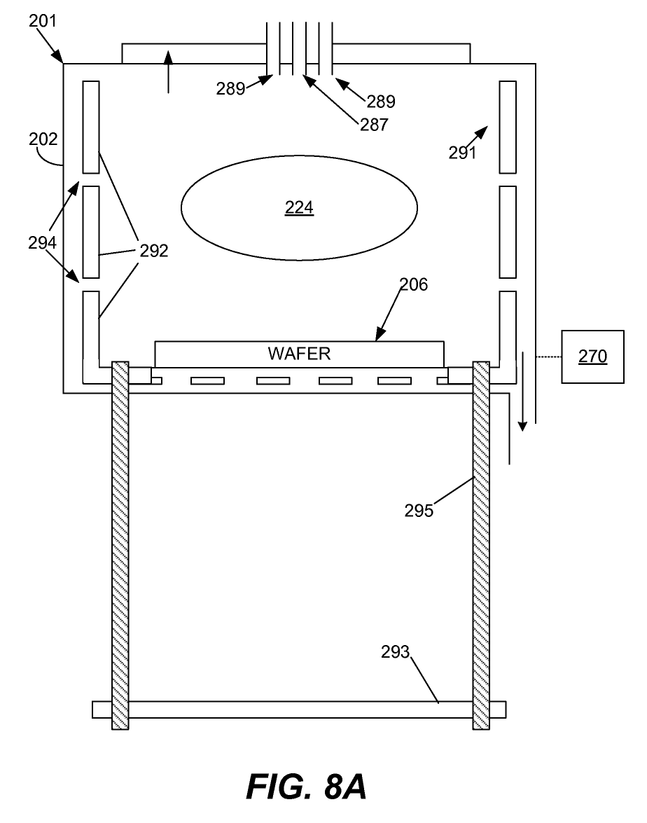

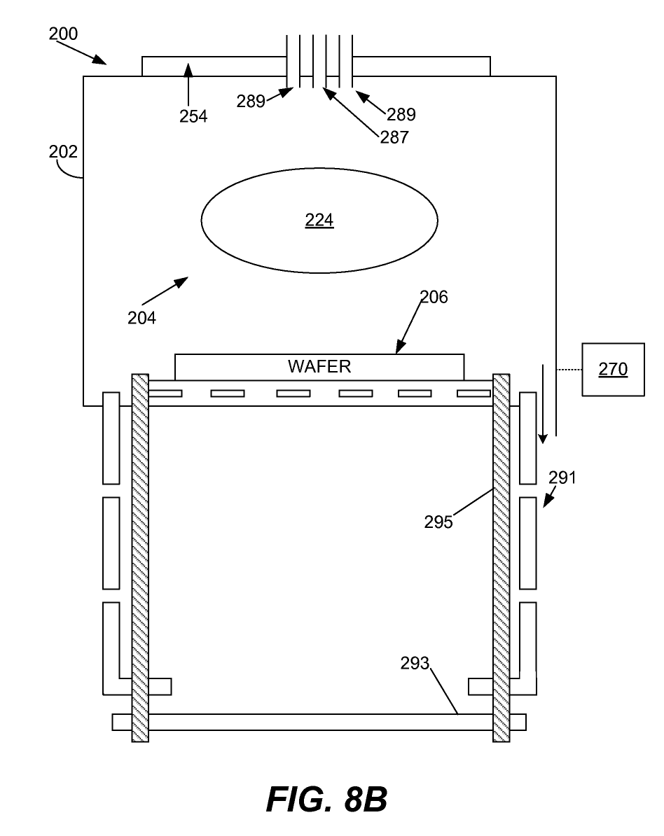

FIG. 7 shows a preferred embodiment in which the gas distribution system 210 includes gas sources 216 and a gas switch 217, where in this example the gas switch 217 comprises a flow control section 704, and a gas switching section 708 in fluid communication with each other. The gas distribution system 210 is preferably controlled by the controller 270, which is connected in control communication to control operation of the gas sources 216, flow control section 704 and gas switching section 708.

In the gas distribution system 210, the gas sources 216 can supply different gases, such as first and second process gases, to the flow control section 704 via respective first and second gas lines 712, 716. The first and second gases can have different compositions and/or gas flow rates from each other.

The flow control section 704 is operable to control the flow rate, and optionally also to adjust the composition, of different gases that can be supplied to the switching section 708. The flow control section 704 can provide different flow rates and/or chemistries of the first and second gases to the switching section 708 via gas passages 720, 724 and 728, 732, respectively. In addition, the flow rate and/or chemistry of the first gas and/or second gas that is supplied to the plasma processing chamber 204 can be different for an inner zone and an outer zone of the ICP chamber. Accordingly, the flow control section 704 can provide desired gas flows and/or gas chemistries across the substrate, thereby enhancing substrate processing uniformity.

In the gas distribution system 210, the switching section 708 is operable to switch from the first gas to the second gas within a short period of time to allow the first gas to be replaced by the second gas in a single zone or multiple zones, e.g., the inner zone and the outer zone, while simultaneously diverting the first gas to the by-pass line, or vice versa. The gas switching section 708 preferably can switch between the first and second gases without the occurrence of undesirable pressure surges and flow instabilities in the flow of either gas. If desired, the gas distribution system 210 can maintain a substantially constant sequential volumetric flow rate of the first and second gases through the plasma processing chamber. The switching section 708, flow control section 704, and gas sources 216 described in detail in U.S. Patent Application Publication Number 2007/0066038 A1, mentioned above, may be used in this embodiment of the invention.

FIG. 8A is a simplified view of the processing system 200, which provides a more detailed view of an embodiment of a driver 293 for the confinement mechanism 291. In FIG. 8A, the confinement mechanism 291 is in a raised position. In this embodiment, the confinement mechanism 291 comprises three rings 292 with two gaps 294 between the rings 292. In the position shown in FIG. 8A, the confinement mechanism 291 provide maximum confinement. Plasma and other gases must pass through the gaps 294 and the gap between the top of the chamber and the top of the confinement mechanism, in order to be exhausted, which increases confinement and pressure in the plasma zone.

In this embodiment, a drive mechanism 293 turns a worm screw drive. 295, which causes a translation motion of the confinement mechanism 291. In this example, the driver 293 lowers the confinement mechanism 291, which increases the gap between the top of the chamber and the top of the confinement mechanism, which lowers the resistance for gas passing from the plasma zone to the exhaust system. FIG. 8B is the simplified view of the processing system 200, after the driver 293 has completely lowered the confinement mechanism 291. In other embodiments depending on the distance of travel, in this case about 10 cm, other mechanisms such as cam systems driven by a stepper motor could be used for the driver mechanism.

In another embodiment the gaps between the rings may be adjustable. In such a configuration, the rings making the confinement mechanism may be independently moved with respect to each other.

The adjustment of the confinement mechanism regulates pressure and confinement volume.

In an embodiment of the invention, either the stripping or the deposition of an inorganic material layer on the organic material layer may also comprise a plurality of cycles which at least two phases per cycle.

The modifications to the ICP system allow the formation of an inorganic layer and inorganic spacers on an organic layer in fast gas switching mode of phase times ˜1 sec. The modifications may also allow in situ etching of the conductor, inorganic dielectric, and organic layers in a single ICP processes chamber. In some embodiments, the modifications may also allow in situ etching of a silicon layer in the ICP process chamber. Such modifications to provide such abilities are not believed to be obvious from the prior art.

While this invention has been described in terms of several preferred embodiments, there are alterations, permutations, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

What is claimed is:

1. An inductively coupled power (ICP) plasma processing chamber for forming semiconductor features, comprising:
a plasma processing chamber, comprising:
a vacuum chamber;
at least one antenna adjacent to the vacuum chamber for providing inductively coupled power in the vacuum chamber;
a substrate support for supporting a silicon substrate within the plasma processing chamber;
a pressure regulator for regulating the pressure in the plasma processing chamber;
a gas inlet for providing gas into the plasma processing chamber; and
a gas outlet for exhausting gas from the plasma processing chamber; and
a gas distribution system in fluid connection with the gas inlet for providing a first gas and a second gas, wherein the gas distribution system can substantially replace one of the first gas and the second gas in the plasma zone with the other of the first gas and the second gas within a period of less than 5 seconds.

2. The ICP plasma processing chamber, as recited in claim 1, further comprising:
a confinement mechanism spaced from the substrate support and the vacuum chamber and within the vacuum chamber, wherein the confinement mechanism defines a plasma zone within confinement region extending from the substrate support to the confinement mechanism; and
a drive system for moving the confinement mechanism in a direction to surround the wafer allowing for a smaller volume surrounding the wafer as compared to the entire chamber volume.

3. The ICP plasma processing chamber, as recited in claim 2, further comprising a temperature controller which is able to provide heating and cooling to the substrate support to provide a temperature range of at least −10° C. to 120° C.

4. The ICP plasma processing chamber, as recited in claim 3, wherein the temperature controller is able to separately heat and cool multiple zones on the substrate and maintain a substrate temperature control of <1° C.

5. The ICP plasma processing chamber, as recited in claim 4, further comprising:
an RF power source electrically connected to the antenna, that provides RF power at a frequency between 13.56 MHz and 100 MHz.

6. The ICP plasma processing chamber, as recited in claim 1, wherein the vacuum chamber comprises a first region and a second region, and wherein the gas distribution system provides the first gas to the first region and a third gas to a second region, wherein the first gas is different than the third gas.

7. The ICP plasma processing chamber, as recited in claim 6, wherein the first gas is different from the third gas in that the first gas has a different flow ratio mixture of gases than the third gas.

8. The ICP plasma processing chamber, as recited in claim 7, wherein the gas distribution system comprises:
gas sources that provides a plurality of different gases;
a gas flow control system in fluid connection to the gas sources that controls flow rate of the different gases; and
a gas switching section in fluid connection with the gas flow control system, which is able to switch between different gases to replace one gas with another gas in less than 5 seconds.

9. A method for forming semiconductor features, comprising:
a) loading a wafer into an inductively coupled plasma (ICP) processing chamber, wherein at least one conductive layer and at least one dielectric layer are formed over the wafer and a mask of an organic material is formed over the at least one conductive layer and at least one dielectric layer;
b) depositing an inorganic material layer on the organic material mask, comprising:
flowing an inorganic material deposition gas into the process chamber;
providing a inductively coupled energy to form the inorganic material deposition gas into a plasma, which deposits a layer of inorganic material on the organic material mask; and
stopping the flow of the inorganic material deposition gas.

10. The method, as recited in claim 9, further comprising forming the inorganic material layer to form inorganic material spacers on sidewalls of the organic material mask.

11. The method, as recited in claim 10, wherein the organic layer is photoresist.

12. The method, as recited in claim 11, wherein the forming the inorganic material comprises chemically reacting the inorganic material layer to form a different inorganic material spacers on sidewalls of the organic material mask.

13. The method, as recited in claim 10, wherein the inorganic material is a silicon containing film, such as SiO₂, SiON, SiC, SiOC, SiNC, or Si₃N₄.

14. The method, as recited in claim 13, further comprising removing the organic material mask between the inorganic material spacers.

15. The method, as recited in claim 10, further comprising:
etching the at least one dielectric layer in the ICP plasma processing chamber; and
etching at least one conductive layer in the ICP plasma processing chamber.

16. The method, as recited in claim 10, further comprising removing the inorganic material spacers

17. The method, as recited in claim 10, further comprising using a confinement mechanism placed around a region between the wafer and a coil to provide plasma confinement.

18. The method, as recited in claim 10, wherein the depositing the inorganic material layer and the forming the inorganic material layer is performed for a plurality of cycles, wherein each cycle has a period of less than 20 seconds.
